(19) United States
(12) Patent Application Publication
(10) Pub. No.: US 2024/0118612 A1
(43) Pub. Date: Apr. 11, 2024

(54) PHOTOSENSITIVE RESIN COMPOSITION, METHOD FOR MANUFACTURING RESIST PATTERN FILM, AND METHOD FOR MANUFACTURING PLATED SHAPED ARTICLE

(71) Applicant: JSR CORPORATION, Tokyo (JP)

(72) Inventors: Keiichi SATOU, Tokyo (JP); Akira Ishii, Tokyo (JP); Takuya Tomita, Tokyo (JP); Kazuhiko Koumura, Tokyo (JP)

(73) Assignee: JSR CORPORATION, Tokyo (JP)

(21) Appl. No.: 18/372,176

(22) Filed: Sep. 25, 2023

(30) Foreign Application Priority Data
Sep. 27, 2022 (JP) 2022-154141

(51) Int. Cl. G03F 7/038; G03F 7/004; G03F 7/031

(52) U.S. Cl. CPC G03F 7/0382; G03F 7/0048; G03F 7/031

(57) ABSTRACT

An embodiment of the present invention relates to a photosensitive resin composition, a method for manufacturing a resist pattern film, and a method for manufacturing a plated shaped article; the photosensitive resin composition comprises (A) an alkali-soluble resin, (B1) a polymerizable compound having at least two (meth)acryloyl groups and at least two hydroxy groups in one molecule and having a ring structure, (C) a photoradical polymerization initiator, (D) at least one compound selected from the group consisting of a nitrogen-containing heterocyclic compound (d1) containing two or more nitrogen atoms, a thiol compound (d2), and a polymerization inhibitor (d3), and (F) a solvent.

### BACKGROUND

### Technological Field

The present invention relates to a photosensitive resin composition, a method for manufacturing a resist pattern film, and a method for manufacturing a plated shaped article.

### Description of the Related Art

These days, connection elements such as bumps of semiconductor elements and display elements such as liquid crystal displays and touch panels are required to be arranged with high accuracy on a substrate.

In general, bumps, etc. are a plated shaped article, and are manufactured by, as described in Patent Literature 1, forming a thick-film resist pattern on a substrate having metal foil such as copper and using the thick-film resist pattern as a mask (mold) to perform plating.

Among thick-film resist patterns, particularly a resist pattern having a film thickness region (≥250 μm) for which it is necessary to apply a photosensitive resin composition three times on a substrate faces increasing demand.

### CITATION LIST

### Patent Literature

Patent Literature 1: JP 2006-285035 A

### SUMMARY

However, it has been found that, in a film thickness region (≥250 μm) for which it is necessary to apply a photosensitive resin composition three times, there is a problem that an unexposed portion (a portion originally expected to be dissolved in a development step) is whitened due to the influence of a thermal history during heating and drying.

An object of the present invention is to provide a photosensitive resin composition capable of suppressing the whitening of an unexposed portion and furthermore capable of forming a resist pattern film excellent in developability and resolution, a method for manufacturing a resist pattern film capable of forming the above resist pattern film, and a method for manufacturing a plated shaped article using the above resist pattern film.

The present invention that achieves the above object relates to, for example, [1] to [14] below.

[1]

A photosensitive resin composition comprising:
(A) an alkali-soluble resin;
(B1) a polymerizable compound having at least two (meth)acryloyl groups and at least two hydroxy groups in one molecule and having a ring structure;
(C) a photoradical polymerization initiator;
(D) at least one compound selected from the group consisting of a nitrogen-containing heterocyclic compound (d1) containing two or more nitrogen atoms, a thiol compound (d2), and a polymerization inhibitor (d3); and
(F) a solvent.
   [2]

The photosensitive resin composition according to [1], wherein the polymerizable compound (B1) has, in one molecule, at least two structures represented by Formula (1) below:

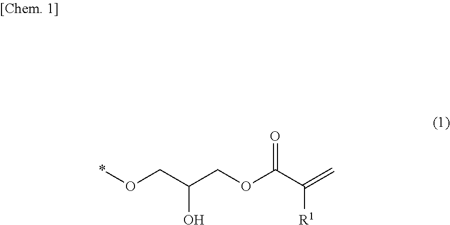

wherein R¹ represents a hydrogen atom or a methyl group, and * represents a bonding position.
   [3]

The photosensitive resin composition according to [1] or [2], wherein the ring structure of the polymerizable compound (B1) is an alicyclic hydrocarbon structure.

[4]

The photosensitive resin composition according to any one of [1] to [3], further including a polymerizable compound (B2) other than the polymerizable compound (B1).

[5]

The photosensitive resin composition according to any one of [1] to [4], wherein the photoradical polymerization initiator (C) comprises an oxime-based photoradical polymerization initiator (C1).

[6]

The photosensitive resin composition according to [5], wherein the photoradical polymerization initiator (C) further comprises a non-oxime-based photoradical polymerization initiator (C2).

[7]

The photosensitive resin composition according to any one of [1] to [6], wherein the compound (D) comprises the nitrogen-containing heterocyclic compound (d1).

[8]

The photosensitive resin composition according to any one of [1] to [7], comprising the compound (D) in a range of 0.05 to 20 parts by mass with respect to 100 parts by mass of the polymerizable compound (B1).

[9]

The photosensitive resin composition according to any one of [1] to [8], wherein the alkali-soluble resin (A) has a phenolic hydroxy group-containing structural unit represented by Formula (2) below:

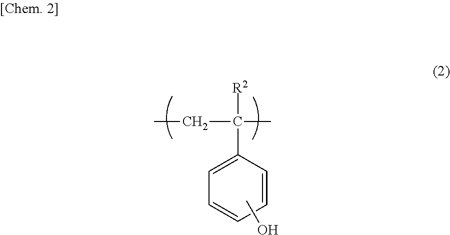

wherein R² represents a hydrogen atom or a methyl group.
   [10]

The photosensitive resin composition according to [9], wherein a content of the phenolic hydroxy group-containing structural units in 100 mass % of the alkali-soluble resin (A) is in a range of 1 to 40 mass %.

[11]

A method for manufacturing a resist pattern film, comprising: a step (1) of applying the photosensitive resin composition according to any one of [1] to [10] onto a substrate to form a resin coating film; a step (2) of exposing the resin coating film to light; and a step (3) of developing the resin coating film after exposure.

[12]

The method for manufacturing a resist pattern film according to [11], wherein a resist pattern film is formed on a copper film.

[13]

The method for manufacturing a resist pattern film according to [11] or [12], wherein a film thickness of the resin coating film formed by the step (1) is 250 μm or more.

[14]

A method for manufacturing a plated shaped article, comprising: a step of using, as a mask, a resist pattern film manufactured by the method according to any one of [11] to [13] to perform plating treatment on the substrate.

According to the photosensitive resin composition of the present invention, the whitening of an unexposed portion can be suppressed, and furthermore a resist pattern film excellent in developability and resolution can be favorably manufactured.

### DETAILED DESCRIPTION OF EMBODIMENTS

### Photosensitive Resin Composition

The photosensitive resin composition of the present invention is a resin composition for forming resist pattern films. The photosensitive resin composition contains an alkali-soluble resin (A), a polymerizable compound (B1) having at least two (meth)acryloyl groups and at least two hydroxy groups in one molecule and having a ring structure, a photoradical polymerization initiator (C), at least one compound (D) selected from the group consisting of a nitrogen-containing heterocyclic compound (d1) containing two or more nitrogen atoms, a thiol compound (d2), and a polymerization inhibitor (d3), and a solvent (F), and can further contain, for example, a polymerizable compound (B2) other than the polymerizable compound (B1) and a surfactant, as necessary.

### Alkali-Soluble Resin (A)

The alkali-soluble resin (A) is a resin having a property of being dissolved in an alkaline developer to such a degree that an intended development treatment can be performed. Examples include alkali-soluble resins described in JP 2008-276194 A, JP 2003-241372 A, JP 2009-531730 T, WO 2010/001691 A, JP 2011-123225 A, JP 2009-222923 A, and JP 2006-243161 A. The weight average molecular weight (Mw) in terms of polystyrene of the alkali-soluble resin (A) measured by gel permeation chromatography is in the range of preferably 1,000 to 1,000,000, more preferably 2,000 to 50,000, and particularly preferably 3,000 to 20,000.

The alkali-soluble resin (A) preferably has a phenolic hydroxy group in terms of improving the developability and pattern shape of the resist pattern film. The alkali-soluble resin (A) having a phenolic hydroxy group is preferably an alkali-soluble resin (A1) having a structural unit represented by Formula (2) below (hereinafter, also referred to as “structural unit (2)”).

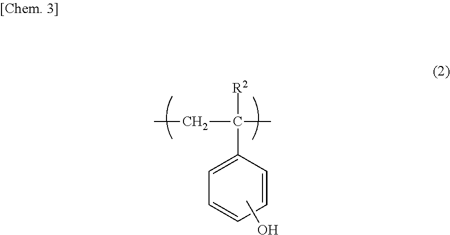

wherein R² represents a hydrogen atom or a methyl group.

By using the alkali-soluble resin (A1) having structural units (2), a resist pattern less likely to swell in a plating step can be obtained. As a result, lifting or peeling of a resist pattern from a base material does not occur; thus, an event where plating liquid seeps to the interface between the base material and the resist pattern can be prevented even when the plating step is performed for a long time. Further, resolution can be improved.

The content of structural units (2) in the alkali-soluble resin (A1) having structural units (2) is in the range of preferably 1 to 40 mass % and more preferably 5 to 30 mass %. By the content of structural units (2) being in the above range, that is, by using such an amount of monomers from which structural units (2) are derived, the molecular weight of the alkali-soluble resin (A1) can be sufficiently increased. Further, a resist pattern less likely to swell in a plating step can be obtained.

### Monomer (2′)

The alkali-soluble resin (A1) having structural units (2) can be obtained by, for example, performing polymerization by using, as some of source monomers, a hydroxy group-containing aromatic vinyl compound (hereinafter also referred to as “monomer (2′)”) such as o-hydroxystyrene, m-hydroxystyrene, p-hydroxystyrene, or p-isopropenylphenol. For these monomers (2′), one kind may be used singly, or two or more kinds may be used in combination.

Among these monomers (2′), p-hydroxystyrene and p-isopropenylphenol are preferable and p-hydroxystyrene is more preferable in terms of obtaining a resin composition capable of forming a resist pattern excellent in long-time plating treatment resistance.

### Monomer (I)

The alkali-soluble resin (A1) having structural units (2) may further have a structural unit derived from another monomer (hereinafter also referred to as “monomer (I)”) which can be copolymerized with monomer (2′).

Examples of the monomer (I) include aromatic vinyl compounds such as styrene, α-methylstyrene, p-methylstyrene, and p-methoxystyrene;
heteroatom-containing alicyclic vinyl compounds such as N-vinylpyrrolidone and N-vinylcaprolactam;
(meth)acrylic acid derivatives having a glycol structure, such as phenoxy diethylene glycol (meth)acrylate, phenoxy triethylene glycol (meth)acrylate, phenoxy tetraethylene glycol (meth)acrylate, phenoxy polyethylene glycol (meth)acrylate, phenoxy dipropylene glycol (meth)acrylate, phenoxy tripropylene glycol (meth)acrylate, phenoxy tetrapropylene glycol (meth)acrylate, lauroxy diethylene glycol (meth)acrylate, lauroxy triethylene glycol (meth)acrylate, lauroxy tetraethylene glycol (meth)acrylate, lauroxy dipropylene glycol (meth)acrylate, lauroxy tripropylene glycol (meth)acrylate, and lauroxy tetrapropylene glycol (meth) acrylate;
cyano group-containing vinyl compounds such as acrylonitrile and methacrylonitrile;
conjugated diolefins such as 1,3-butadiene and isoprene;
carboxyl group-containing vinyl compounds such as acrylic acid and methacrylic acid;
(meth)acrylic acid esters such as methyl (meth)acrylate, ethyl (meth)acrylate, n-propyl (meth)acrylate, n-butyl (meth)acrylate, 2-hydroxyethyl (meth) acrylate, 2-hydroxypropyl (meth) acrylate, polyethylene glycol mono(meth)acrylate, polypropylene glycol mono(meth)acrylate, glycerol mono(meth)acrylate, phenyl (meth)acrylate, benzyl (meth)acrylate, cyclohexyl (meth)acrylate, isobornyl (meth)acrylate, and tricyclodecanyl (meth) acrylate; and
p-hydroxyphenyl(meth)acrylamide. For these monomers (I), one kind may be used singly, or two or more kinds may be used in combination.

Among these monomers (I), styrene, acrylic acid, methacrylic acid, methyl (meth)acrylate, ethyl (meth) acrylate, n-butyl (meth) acrylate, tricyclodecanyl (meth)acrylate, benzyl (meth)acrylate, isobornyl (meth)acrylate, and p-hydroxyphenyl (meth)acrylamide are preferable, for example.

The alkali-soluble resin (A1) can be manufactured by, for example, radical polymerization. Examples of the polymerization method include an emulsion polymerization method, a suspension polymerization method, a solution polymerization method, and a bulk polymerization method.

### Polymerizable Compound (B1)

When the photosensitive resin composition of a negative-type of the present invention is applied onto a substrate to form a coating film and the coating film is exposed to light, the polymerizable compound (B1) (hereinafter, also referred to as “compound (B1)”) is, in the exposed site, polymerized at the radically polymerizable unsaturated double bond group to form a crosslinked body by the action of a radical generated from the photoradical polymerization initiator (C).

Compound (B1) has at least two (meth)acryloyl groups and at least two hydroxy groups in one molecule, and has a ring structure. As compound (B1), a compound (B1a) having, in one molecule, at least two structures represented by Formula (1) below is preferable because a resist pattern film can be formed without corroding a copper film of a base material, particularly a base material having a copper film on a surface, even when the development speed is increased in a method for forming a resist pattern film.

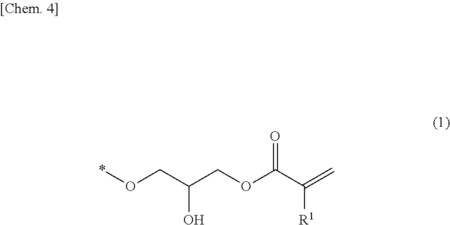

wherein R¹ represents a hydrogen atom or a methyl group, and * represents a bonding position.

By the method for forming a resist pattern film, a resist pattern film can be formed without corroding a copper film of a base material, particularly a base material having a copper film on a surface, even when the development speed is increased. For this effect, it is surmised that compound (B1) contained in the resin film formed on the base material acts characteristically.

When forming a resist pattern film on a base material, if the development speed is increased, the base material portion under a hole formed in the resin film is likely to corrode. For example, in the case of a base material having a copper film on a surface, a needle-like defect occurs in the copper film portion under a hole. In particular, in the case where a resist pattern is formed on TSVs, defects occur significantly. The reason why a defect occurs is surmised to be that, since at the time of development the developer stays in the hole and is not discharged from the hole, the copper film is in contact with the alkaline developer for a long time and the copper corrodes.

Compound (B1) remaining on the copper film can be easily removed by, for example, performing a cleaning operation after development, for example bringing water into contact. Therefore, compound (B1) does not influence subsequent manufacturing of a plated shaped article such as a bump. The reason why compound (B1) is easily removed by a cleaning operation is surmised to be that the ratio of hydroxy groups in compound (B1) is not high and the affinity of compound (B1) to the copper film is not too strong. In particular, in compound (B1a), since the ratio of hydroxy groups in compound (B1a) is defined to a certain range by Formula (1), it is surmised that such a strength of affinity to the copper film that a certain amount remains on the copper film at the time of development and is completely removed by subsequent cleaning is achieved.

Compound (B1) contains at least one ring structure, preferably 1 to 3 ring structures.

The ring structure contained in compound (B1) is not particularly limited, but is preferably an alicyclic hydrocarbon structure.

Here, the alicyclic hydrocarbon structure means a ring derived from an alicyclic hydrocarbon compound, and the alicyclic hydrocarbon compound may be saturated or unsaturated and may have a single ring or multiple rings.

Examples of the alicyclic hydrocarbon structure include a cycloalkane ring such as a cyclohexane ring, a cycloalkene ring such as cyclohexene, a bicycloalkane ring such as a norbornane ring, and a bicycloalkene ring such as norbornene, but are not limited thereto. Among them, a cycloalkane ring is preferable, a cycloalkane ring having 4 to 7 carbon atoms is more preferable, and a cyclohexane ring is still more preferable.

Examples of the compound (B1) include a compound obtained by reaction of, for example, epoxy (meth)acrylate and a carboxylic acid, an alcoholic compound, or a phenolic compound, and a reaction product of diglycidyl ether or a carboxylic acid diglycidyl ester and (meth)acrylic acid. Examples of the carboxylic acid compound include alicyclic dicarboxylic acids such as hexahydrophthalic acid and hexahydroterephthalic acid, aromatic dicarboxylic acids such as phthalic acid and terephthalic acid, aromatic tricarboxylic acids such as trimesic acid, and aromatic tetracarboxylic acids such as benzophenone tetracarboxylic acid, biphenyl tetracarboxylic acid, and oxydiphthalic acid. Examples of the alcoholic compound and the phenolic compound include alicyclic diols such as cyclohexanediol, and phenol derivatives such as biphenols and substitution products thereof, bisphenol A and derivatives thereof, biphenol ethers and derivatives thereof, and novolac oligomers and derivatives thereof.

Examples of the diglycidyl ether include alicyclic diglycidyl ethers such as hydrogenated bisphenol A diglycidyl ether, and aromatic diglycidyl ethers such as bisphenol A type epoxy resins.

Examples of the carboxylic acid diglycidyl ester include phthalic acid diglycidyl ester, terephthalic acid diglycidyl ester, hexahydrophthalic acid diglycidyl ester, and hexahydroterephthalic acid diglycidyl ester.

These can be used singly or in combination of two or more.

These reactions can be performed according to usual methods.

Specific examples of compound (B1) include a polymerizable compound (B11) used in Examples described later. When compound (B1) is a polymerizable compound having a hydroxy group and a ring structure, like compound (B11), swelling of a pattern can be suppressed while good developability is exhibited, and therefore a resist pattern film excellent in developability and pattern shape can be formed.

The content of compound (B1) in the photosensitive resin composition of the present invention is preferably 1 to 100 parts by mass, more preferably 1 to 50 parts by mass, and particularly preferably 1 to 20 parts by mass with respect to 100 parts by mass of the alkali-soluble resin (A). When the content of compound (B1) is in this range, the generation of residues after development can be suppressed while a good shape is kept during forming patterns, especially when a resin film is formed with a high film thickness.

### Polymerizable Compound (B2) Other Than Polymerizable Compound (B1)

The photosensitive resin composition of the present invention preferably contains a polymerizable compound (B2) other than the above polymerizable compound (B1).

When the polymerizable compound (B2) (hereinafter, also referred to as “compound (B2)”) other than the above polymerizable compound (B1) is blended in the photosensitive resin composition, the development speed of the resin film is reduced, and therefore the development speed of the resin film can be regulated. The blending of compound (B2) is effective when the development speed of the resin film is too high.

Examples of compound (B2) include a compound having two ethylenically unsaturated double bonds, such as 1,3-butanediol di(meth)acrylate, 1,6-hexanediol di(meth)acrylate, ethylene glycol di(meth)acrylate, diethylene glycol di(meth)acrylate, neopentyl glycol di(meth)acrylate, triethylene glycol di(meth)acrylate, tetraethylene glycol di(meth)acrylate, polyethylene glycol diacrylate, bis(acryloyloxyethyl) ether of bisphenol A, ethoxylated bisphenol A di(meth)acrylate, propoxylated neopentyl glycol di(meth)acrylate, ethoxylated neopentyl glycol di(meth)acrylate, and 3-methylpentanediol di(meth)acrylate, and a compound having three or more ethylenically unsaturated double bonds, such as trimethylolpropane tri(meth)acrylate, pentaerythritol tri(meth)acrylate, tris(2-hydroxyethyl) isocyanurate tri(meth)acrylate, ethoxylated trimethylolpropane tri(meth)acrylate, propoxylated trimethylolpropane tri(meth)acrylate, pentaerythritol tetra(meth)acrylate, dipentaerythritol penta(meth)acrylate, dipentaerythritol hexa(meth)acrylate, tripentaerythritol tetra(meth)acrylate, tripentaerythritol penta(meth)acrylate, tripentaerythritol hexa(meth)acrylate, tripentaerythritol hepta(meth)acrylate, tripentaerythritol octa(meth)acrylate, a reaction product of pentaerythritol tri(meth)acrylate and an acid anhydride, a reaction product of dipentaerythritol penta(meth)acrylate and an acid anhydride, a reaction product of tripentaerythritol hepta(meth)acrylate and an acid anhydride, caprolactone-modified trimethylolpropane tri(meth)acrylate, caprolactone-modified pentaerythritol tri(meth)acrylate, caprolactone-modified tris(2-hydroxyethyl) isocyanurate tri(meth)acrylate, caprolactone-modified pentaerythritol tetra(meth)acrylate, caprolactone-modified dipentaerythritol penta(meth)acrylate, caprolactone-modified dipentaerythritol hexa(meth)acrylate, caprolactone-modified tripentaerythritol tetra(meth)acrylate, caprolactone-modified tripentaerythritol penta(meth)acrylate, caprolactone-modified tripentaerythritol hexa(meth)acrylate, caprolactone-modified tripentaerythritol hepta(meth)acrylate, caprolactone-modified tripentaerythritol octa(meth)acrylate, a reaction product of caprolactone-modified pentaerythritol tri(meth)acrylate and an acid anhydride, a reaction product of caprolactone-modified dipentaerythritol penta(meth)acrylate and an acid anhydride, and caprolactone-modified tripentaerythritol hepta(meth)acrylate and an acid anhydride.

Examples of commercially available products of compound (B2) include ARONIX M-8060 (manufactured by Toagosei Co., Ltd.), A9300-1CL (manufactured by Shin-Nakamura Chemical Co., Ltd.), and Epoxy Ester 70PA (manufactured by Kyoeisha Chemical Co., Ltd.).

The blending amount of compound (B2) can be determined according to the purpose as appropriate, and is, for example, preferably 1 to 100 parts by mass, more preferably 5 to 50 parts by mass, and particularly preferably 15 to 50 parts by mass with respect to 100 parts by mass of the alkali-soluble resin (A). When the content of compound (B2) is in this range, the balance among coating property, developability, sensitivity, and resolution as a photosensitive resin composition is good.

### Photoradical Polymerization Initiator (C)

The photoradical polymerization initiator (C) is a compound that generates radicals by irradiation with light to initiate radical polymerization of compound (B1).

The content of the photoradical polymerization initiator (C) is preferably 1 to 40 parts by mass, more preferably 3 to 35 parts by mass, and particularly preferably 3 to 20 parts by mass with respect to 100 parts by mass of the polymerizable compound (B1). When the content of the photoradical polymerization initiator (C) is in the above range, a suitable amount of radicals is obtained, and excellent resolution is obtained.

The photoradical polymerization initiator (C) is roughly categorized into an oxime-based photoradical polymerization initiator (C1) and a non-oxime-based photoradical polymerization initiator (C2). Among them, the oxime-based photoradical polymerization initiator (C1), particularly a photoradical polymerization initiator having an oxime ester structure, is preferable in terms of sensitivity.

The photoradical polymerization initiator having an oxime ester structure may have geometric isomers due to the double bond of the oxime, but these are not distinguished, and both are included in the photoradical polymerization initiator (C).

Examples of the photoradical polymerization initiator having an oxime ester structure include photoradical polymerization initiators described in WO 2010/146883 A, JP 2011-132215 A, JP 2008-506749 T, JP 2009-519904 T, and JP 2009-519991 T.

Specific examples of the photoradical polymerization initiator having an oxime ester structure include N-benzoyloxy-1-(4-phenylsulfanylphenyl)butane-1-one-2-imine, N-ethoxycarbonyloxy-1-phenylpropane-1-one-2-imine, N-benzoyloxy-1-(4-phenylsulfanylphenyl)octane-1-one-2-imine, N-acetoxy-1-[9-ethyl-6-(2-methylbenzoyl)-9H-carbazole-3-yl]ethane-1-imine, and N-acetoxy-1-[9-ethyl-6-{2-methyl-4-(3,3-dimethyl-2,4-dioxacyclopentanylmethyloxy)benzoyl}-9H-carbazol-3-yl]ethane-1-imine.

Examples of commercially available products of the photoradical polymerization initiator having an oxime ester structure include TR-PBG-3057 (manufactured by TRONLY) and ADEKA ARKLS NCI-930 (manufactured by ADEKA Corporation).

On the other hand, examples of the non-oxime-based photoradical polymerization initiator (C2) include organic halogenated compounds, oxydiazole compounds, carbonyl compounds, ketal compounds, benzoin compounds, acridine compounds, organic peroxide compounds, azo compounds, coumarin compounds, azide compounds, metallocene compounds, hexaarylbiimidazole compounds, organic boric acid compounds, disulfonic acid compounds, onium salt compounds, and acylphosphine (oxide) compounds. Among them, acylphosphine (oxide) compounds are preferable in terms of the degree of development.

Examples of the acylphosphine (oxide) compound include 2,4,6-trimethylbenzoyl-diphenylphosphine oxide and bis(2,4,6-trimethylbenzoyl)-phenylphosphine oxide.

Examples of commercially available products of the acylphosphine (oxide) compound include Omnirad TPO H (manufactured by IGM Resins B.V.) and Omnirad 819 (manufactured by IGM Resins B.V.).

For these photoradical polymerization initiators (C), one kind may be used singly, or two or more kinds may be used in combination, and a preferred form is to use at least one oxime-based photoradical polymerization initiator (C1) and at least one non-oxime-based photoradical polymerization initiator (C2). When the oxime-based photoradical polymerization initiator (C1) and the non-oxime-based photoradical polymerization initiator (C2) are used in combination, the shape of the entire pattern can be improved by virtue of the fact that the cure extent of the surface layer of the pattern is increased by the oxime-based photoradical polymerization initiator (C1) and the cure extent of the interior of the pattern is increased by the non-oxime-based photoradical polymerization initiator (C2); thus, this case is preferable.

### Compound (D)

Compound (D) is at least one compound selected from the group consisting of a nitrogen-containing heterocyclic compound (d1) containing two or more nitrogen atoms, a thiol compound (d2), and a polymerization inhibitor (d3). It is preferable that the photosensitive resin composition contain, among them, the nitrogen-containing heterocyclic compound (d1) in terms of less influence on sensitivity.

It is presumed that compound (D) suppresses thermal polymerization on the surface of the copper substrate and thereby suppresses the whitening of an unexposed portion, which is presumably derived from thermal crosslinking.

The content of compound (D) is preferably 0.05 to 20 parts by mass and more preferably 0.1 to 10 parts by mass with respect to 100 parts by mass of the polymerizable compound (B1). When the content of compound (D) is in the above range, the whitening of an unexposed portion can be suppressed.

Nitrogen-containing heterocyclic compound (d1) containing two or more nitrogen atoms

The nitrogen-containing heterocyclic compound (d1) containing two or more nitrogen atoms is a compound that is easily coordinated to copper, and therefore it is presumed that, by forming a protective film on the copper surface, the nitrogen-containing heterocyclic compound (d1) can prevent the polymerizable compound from forming a crosslinked body due to heat on the copper surface.

The nitrogen-containing heterocyclic compound (d1) contains two or more nitrogen atoms, and preferably contains three or more nitrogen atoms. It is inferred that a heterocyclic compound containing one nitrogen atom has only weak interaction with copper and is inferior in effect as a protective agent by forming a protective film.

The nitrogen-containing heterocyclic compound (d1) is not particularly limited; examples include imidazoles, triazoles, and purine derivatives, and preferred examples include imidazoles and triazoles. These may be used singly or in combination of two or more.

The imidazoles are not particularly limited, and examples include imidazole, 2-methylimidazole, 2-ethylimidazole, 2-propylimidazole, 2-isopropylimidazole, 2-butylimidazole, 2-t-butylimidazole, 2-pentylimidazole, 2-hexylimidazole, 2-heptylimidazole, 2-(1-ethylpentyl)imidazole, 2-octylimidazole, 2-nonylimidazole, 2-decylimidazole, 2-undecylimidazole, 2-dodecylimidazole, 2-tridecylimidazole, 2-tetradecylimidazole, 2-pentadecylimidazole, 2-hexadecylimidazole, 2-heptadecylimidazole, 2-(1-methylpentyl)imidazole, 2-(1-ethylpentyl)imidazole, 2-(1-heptyldecyl)imidazole, 2-(5-hexenyl)imidazole, 2-(9-octenyl)imidazole, 2-(8-heptadecenyl)imidazole, 2-(4-chlorobutyl)imidazole, 2-(9-hydroxynonyl) imidazole, 2-ethyl-4-methylimidazole, 2-undecyl-4-methylimidazole, 2-heptadecyl-4-methylimidazole, 2-phenylimidazole, 2-phenyl-4-methylimidazole, 2-(1-naphthyl)imidazole, 2-(1-naphthyl)-4-methylimidazole, 2-(2-naphthyl)imidazole, 2-(2-naphthyl)-4-methylimidazole, 2-methyl-4-phenylimidazole, 4-phenylimidazole, 4-methylimidazole, 4-isopropylimidazole, 4-octylimidazole, 2,4,5-trimethylimidazole, and benzimidazole. Benzimidazole is particularly preferable.

The triazoles are not particularly limited, and examples include 1,2,3-triazole, 1,2,4-triazole, 1-methyl-1,2,4-triazole, 1-ethyl-1,2,4-triazole, 1-propyl-1,2,4-triazole, 1-isopropyl-1,2,4-triazole, 1-butyl-1,2,4-triazole, 1-methyl-1,2,3-triazole, 1-ethyl-1,2,3-triazole, 1-propyl-1,2,3-triazole, 1-isopropyl-1,2,3-triazole, 1-butyl-1,2,3-triazole, 1-methylbenzotriazole, 1,2,3-benzotriazole, and 5-methyl-1H-benzotriazole. 1,2,3-Benzotriazole is particularly preferable.

Examples of purine derivatives include purine, adenine, guanine, hypoxanthine, xanthine, theobromine, caffeine, uric acid, isoguanine, 2,6-diaminopurine, 9-methyladenine, 2-hydroxyadenine, 2-methyladenine, 1-methyladenine, N-methyladenine, N,N-dimethyladenine, 2-fluoroadenine, 9-(2-hydroxyethyl)adenine, guanine oxime, N-(2-hydroxyethyl)adenine, 8-aminoadenine, 6-amino-8-phenyl-9H-purine, 1-ethyladenine, 6-ethylaminopurine, 1-benzyladenine, N-methylguanine, 7-(2-hydroxyethyl)guanine, N-(3-chlorophenyl)guanine, N-(3-ethylphenyl)guanine, 2-azaadenine, 5-azaadenine, 8-azaadenine, 8-azaguanine, 8-azapurine, 8-azaxanthin, and 8-azahypoxanthine, and derivatives thereof.

### Thiol Compound (d2)

The thiol compound (d2) is, similarly to the above nitrogen-containing heterocyclic compound (d1), a compound that is easily coordinated to copper, and therefore it is presumed that, by forming a protective film on the copper surface, the thiol compound (d2) can prevent the polymerizable compound from forming a crosslinked body due to heat on the copper surface.

The thiol compound (d2) may be either a monofunctional thiol compound or a polyfunctional thiol compound, but is preferably a polyfunctional thiol compound (d2-a) from the viewpoint of further enhancing the sensitivity of the photosensitive resin composition to exposure light.

The monofunctional thiol compound is a compound having one thiol group (mercapto group) in the molecule. Examples of the monofunctional thiol compound include stearyl-3-mercaptopropionate.

The polyfunctional thiol compound (d2-a) is a compound having two or more thiol groups (mercapto groups) in the molecule. The polyfunctional thiol compound is preferably a low molecular weight compound having a molecular weight of 100 or more; specifically, the molecular weight is more preferably 100 to 1,500 and still more preferably 150 to 1,000.

The number of functional groups of the polyfunctional thiol compound (d2-a) is preferably 2 to 10, more preferably 2 to 8, and still more preferably 2 to 4. When the number of functional groups is increased, film strength is excellent, whereas when the number of functional groups is reduced, storage stability is excellent. In the case of the above range, both of them can be achieved.

As the above polyfunctional thiol compound (d2-a), both an aromatic polyfunctional thiol compound and an aliphatic polyfunctional thiol compound can be used, and as the aromatic polyfunctional thiol compound, a compound having a benzothiazole structure is more preferable.

Examples of the compound having a benzothiazole structure include benzothiazole and 2-mercaptobenzothiazole. Among these, 2-mercaptobenzothiazole is preferable.

Examples of the aliphatic polyfunctional thiol compound include pentaerythritol tetrakis(3-mercaptobutyrate), 1,4-bis(3-mercaptobutyryloxy)butane, 1,3,5-tris(3-mercaptobutyryloxyethyl)-1,3,5-triazine-2,4,6(1H,3H,5H)-trione, trimethylolpropane tris(3-mercaptobutyrate), trimethylolethane tris(3-mercaptobutyrate), trimethylolpropane tris(3-mercaptopropionate), tris[(3-mercaptopropionyloxy)ethyl] isocyanurate, pentaerythritol tetrakis(3-mercaptopropionate), tetraethylene glycol bis(3-mercaptopropionate), and dipentaerythritol hexakis(3-mercaptopropionate); among them, more preferred examples include pentaerythritol tetrakis(3-mercaptobutyrate), 1,4-bis(3-mercaptobutyryloxy)butane, and 1,3,5-tris(3-mercaptobutyryloxyethyl)-1,3,5-triazine-2,4,6(1H,3H,5H)-trione.

Examples of commercially available products of the aliphatic polyfunctional thiol compound include C3TS-G (manufactured by Shikoku Chemicals Corporation), Karenz MT-PE-1, Karenz MT-BD-1, Karenz MT-NR-1, TPMB, and TEMB (all of these are manufactured by Showa Denko K.K.), and TMMP, TEMPIC, PEMP, EGMP-4, and DPMP (all of these are manufactured by Sakai Chemical Industry Co., Ltd.).

For these thiol compounds (C), one kind may be used singly, or two or more kinds may be used in combination.

### Polymerization Inhibitor (d3)

It is inferred that the polymerization inhibitor (d3) suppresses the formation of a crosslinked body due to heat of the polymerizable compound on the copper surface. The polymerization inhibitor (d3) can also contribute to an improvement of the storage stability of the photosensitive resin composition.

Examples of the polymerization inhibitor (d3) include hydroquinone, a monoesterified product of hydroquinone, N-nitrosodiphenylamine, benzoquinone, phenothiazine, p-methoxyphenol, p-t-butylcatechol, N-phenylnaphthylamine, 2,6-di-t-butyl-p-methylphenol, chloranil, and pyrogallol.

The polymerization inhibitor (d3) is preferably a phenolic polymerization inhibitor (d3-a) such as hydroquinone, p-methoxyphenol, or catechol.

Specific examples of the phenolic polymerization inhibitor (d3-a) include (d31) and (d32) used in Examples described later.

For these polymerization inhibitors (d3), one kind may be used singly, or two or more kinds may be used in combination.

### Solvent (F)

By containing the solvent (F), the photosensitive resin composition of the present invention can improve the handleability of the photosensitive resin composition, regulate viscosity, and improve storage stability.

Examples of the solvent (F) include
alcohols such as methanol, ethanol, and propylene glycol;
cyclic ethers such as tetrahydrofuran and dioxane;
glycols such as ethylene glycol and propylene glycol;
alkylene glycol monoalkyl ethers such as ethylene glycol monomethyl ether, propylene glycol monomethyl ether, and propylene glycol monoethyl ether;
alkylene glycol monoalkyl ether acetates such as ethylene glycol monomethyl ether acetate, propylene glycol monomethyl ether acetate, and propylene glycol monoethyl ether acetate;
aromatic hydrocarbons such as toluene and xylene;
ketones such as acetone, methyl ethyl ketone, methyl isobutyl ketone, cyclohexanone, and 4-hydroxy-4-methyl-2-pentanone;
esters such as ethyl acetate, butyl acetate, 3-methoxybutyl acetate, ethyl ethoxyacetate, ethyl hydroxyacetate, ethyl 2-hydroxypropionate, ethyl 2-hydroxy-2-methylpropionate, methyl 2-hydroxy-3-methylbutanoate, methyl 3-methoxypropionate, ethyl 3-methoxypropionate, ethyl 3-ethoxypropionate, methyl 3-ethoxypropionate, and ethyl lactate; and
N-methylformamide, N,N-dimethylformamide, N-methylformanilide, N-methylacetamide, N,N-dimethylacetamide, N-methylpyrrolidone, dimethyl sulfoxide, benzyl ethyl ether, dihexyl ether, acetonylacetone, isophorone, caproic acid, caprylic acid, 1-octanol, 1-nonanol, benzyl alcohol, benzyl acetate, ethyl benzoate, diethyl oxalate, γ-butyrolactone, ethylene carbonate, propylene carbonate, and phenyl Cellosolve acetate.

The amount of the ethylene glycol-based solvent used in the present invention is preferably 50 mass % or more and more preferably 80 mass % or more with respect to 100 mass % of all the solvents. By using an ethylene glycol-based solvent in the above range as the solvent (F), it becomes easier to form resin films having greatly different film thicknesses.

The amount of the solvent (F) used is preferably 50 parts by mass or more, more preferably 60 to 300 parts by mass, and particularly preferably 70 to 200 parts by mass with respect to 100 parts by mass of the alkali-soluble resin (A).

### Other Components

In the resin composition, in addition to the components described above, components such as a thermal polymerization inhibitor for improving the storage stability of the resin composition, a surfactant, an adhesion aid for improving the adhesiveness between the resin film and the substrate, a sensitizer for increasing sensitivity, and an inorganic filler for improving the strength of the resin film may be blended to the extent that the object and characteristics of the present invention are not impaired, as necessary.

### Surfactant

When a surfactant is blended in the resin composition, properties such as coating property, defoaming ability, and leveling ability can be improved.

As the surfactant, a commercially available surfactant can be used. Specific examples of commercially available surfactants include NBX-15, FTX-204D, FTX-208D, FTX-212D, FTX-216D, FTX-218, FTX-220D, and FTX-222D (all of these are manufactured by NEOS Company Limited), BM-1000 and BM-1100 (both of these are manufactured by BM Chemie), Megafac F142D, Megafac F172, Megafac F173, and Megafac F183 (all of these are manufactured by Dainippon Ink and Chemicals, Inc.), Fluorad FC-135, Fluorad FC-170C, Fluorad FC-430, and Fluorad FC-431 (all of these are manufactured by Sumitomo 3M Limited), Surflon S-112, Surflon S-113, Surflon S-131, Surflon S-141, and Surflon S-145 (all of these are manufactured by Asahi Glass Co., Ltd.), and SH-28PA, SH-190, SH-193, SZ-6032, and SF-8428 (all of these are manufactured by Dow Corning Toray Silicone Co., Ltd.).

### Method for Preparing Photosensitive Resin Composition

The photosensitive resin composition of the present invention can be prepared by uniformly mixing the components. In order to remove dust, after the components are uniformly mixed, the resulting mixture may be filtered with a filter, for example.

### Method for Manufacturing Resist Pattern Film

A method for manufacturing a resist pattern film of the present invention includes steps 1 to 3 below.

Step 1: a step of applying the photosensitive resin composition onto a substrate to form a resin coating film

Step 2: a step of exposing the resin coating film to light

Step 3: a step of developing the resin coating film after exposure

### Step (1)

In step (1), the photosensitive resin composition is applied onto a substrate to form a resin coating film.

Examples of the substrate include a semiconductor substrate, a glass substrate, a silicon substrate, and a substrate formed by providing various metal films (in particular, a copper film is preferred.) on a surface of a semiconductor plate, a glass plate, or a silicon plate. The shape of the substrate is not particularly limited. The shape may be a flat plate shape or a shape formed by providing recesses (holes) in a flat plate like a silicon wafer. In the case of a substrate having recesses and also a copper film on the surface, the copper film may be provided at the bottom of the recess as in a TSV structure.

As a method for applying the photosensitive composition, for example, a spray method, a roll coating method, a spin coating method, a slit die coating method, a bar coating method, or an inkjet method can be employed, and particularly the spin coating method is preferable. In the case of the spin coating method, the rotation speed is preferably 800 to 3000 rpm and more preferably 800 to 2000 rpm, and the rotation time is preferably 1 to 300 seconds and more preferably 5 to 200 seconds. After spin coating of the photosensitive composition is performed, the resulting resin coating film is heated and dried at preferably 50 to 180° C., more preferably 60 to 150° C., and particularly preferably 70 to 130° C. for about 1 to 30 minutes.

The film thickness of the resin coating film is preferably 200 to 400 μm; in particular, when a pattern is formed with a high film thickness of 250 μm or more, at which the whitening of an unexposed portion and residues after development are significant, the effect of the present invention is exhibited; thus, this case is preferable.

### Step (2)

In step (2), the resin coating film is exposed to light. That is, the resin coating film is selectively exposed to light so that a resist pattern film is obtained in step (3).

The resin coating film is usually exposed to light by using, for example, a contact aligner, a stepper, or a scanner via a desired photomask. As the exposure light, light having a wavelength of 200 to 500 nm (example: the i-line (365 nm)) is used. The amount of exposure varies depending on, for example, the types and blending amounts of components in the resin coating film and the thickness of the coating film, and is preferably 1 to 10,000 mJ/cm² in the case of using the i-line as exposure light.

Further, heat treatment can be performed after exposure. The conditions of heat treatment after exposure are determined according to, for example, the types and blending amounts of components in the resin coating film and the thickness of the resin coating film as appropriate, and are preferably 70 to 180° C. and 1 to 60 minutes.

### Step (3)

In step (3), the resin coating film after exposure is developed. Thus, a resist pattern film is formed.

As the developer, for example, an aqueous solution containing sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5.4.0]-7-undecene, or 1,5-diazabicyclo[4.3.0]-5-nonane can be used. Also, an aqueous solution in which an appropriate amount of a water-soluble solvent such as methanol or ethanol and/or a surfactant is added to the above aqueous alkaline solution can be used as a developer.

The development time varies depending on, for example, the types and blending ratios of components in the composition and the thickness of the coating film, and is preferably 10 to 1200 seconds, more preferably 30 to 1000 seconds, and particularly preferably 60 to 900 seconds. The method of development may be any of a liquid putting method, a dipping method, a paddle method, a spraying method, and a shower developing method, for example.

It is surmised that, depending on the development time, compound (B1) contained in an unexposed portion of the resin coating film is not completely removed but a certain amount of compound (B1) adheres to the base material and remains on the base material. Thus, in step (3), after the operation of bringing the aqueous alkaline solution into contact with the resin coating film is performed, cleaning may be performed in order to remove compound (B1) remaining on the base material. The cleaning can be performed by, for example, bringing water into contact with the base material. The time to keep water in contact is, for example, 60 to 600 seconds. The contact of water can be performed by, for example, applying running water or spraying water.

After that, air drying may be performed using, for example, an air gun, or drying may be performed under a heating condition such as on a hot plate or in an oven.

### Method for Manufacturing Plated Shaped Article

A method for manufacturing a plated shaped article of the present invention includes a step of performing plating treatment on the substrate by using, as a mask, a resist pattern film formed by the method for manufacturing a resist pattern film described above.

Examples of the plated shaped article include a bump and a wiring line.

The formation of a resist pattern film is performed according to the method for manufacturing a resist pattern film described above.

Examples of the plating treatment include wet plating treatments such as electrolytic plating treatment, electroless plating treatment, and hot dipping treatment, and dry plating treatments such as chemical vapor deposition and sputtering. In the case of forming a wiring line or a connection terminal in processing at a wafer level, plating treatment is usually performed by electrolytic plating treatment.

Before electrolytic plating treatment is performed, the surface of the inner wall of the resist pattern can be subjected to pre-treatment such as ashing treatment, flux treatment, or desmear treatment in order to enhance the affinity between the surface of the inner wall of the resist pattern and the plating solution.

In the case of electrolytic plating treatment, a layer formed on the inner wall of the resist pattern by sputtering or electroless plating treatment can be used as a seed layer, and in the case of using, as the substrate, a substrate having a metal film on a surface, the metal film can be used as a seed layer.

A barrier layer may be formed before the seed layer is formed, or the seed layer may be used as a barrier layer.

Examples of the plating solution used for electrolytic plating treatment include, for example, a copper plating solution containing copper sulfate or copper pyrophosphate; a gold plating solution containing gold potassium cyanide; and a nickel plating solution containing nickel sulfate or nickel carbonate.

For the plating treatment, different plating treatments can be sequentially performed. For example, a solder copper pillar bump can be formed by first performing copper plating treatment, next performing nickel plating treatment, and next performing molten solder dipping treatment.

### EXAMPLES

The present invention will now be described more specifically based on Examples, but the present invention is not limited to these Examples.

The weight average molecular weight (Mw) of the alkali-soluble resin is a value calculated in terms of polystyrene in a gel permeation chromatography method under the following conditions.
Column: TSKgel SuperMultipore HZ-M manufactured by Tosoh Corporation
Solvent: tetrahydrofuran
Column temperature: 40° C.
Detection method: refractive index method
Standard substance: polystyrene
GPC apparatus: apparatus name: “HLC-8320-GPC”, manufactured by Tosoh Corporation

### Manufacturing of Photosensitive Resin Composition

### Examples 1A to 16A and Comparative Examples 1A to 11A

Using propylene glycol monomethyl ether acetate as a solvent, the respective amounts of the components shown in Table 1 below were added to the solvent such that the solid content concentration shown in Table 1 was obtained, mixing was performed, and filtering was performed with a capsule filter (pore size: 1 μm); thus, a photosensitive resin composition of each of Examples 1A to 16A and Comparative Examples 1A to 11A was manufactured.

TABLE 1

| Components | | Example | Example | Example | Example | Example | Example | Example | Example | Example |
|---|---|---|---|---|---|---|---|---|---|---|
| (parts by mass) | | 1A | 2A | 3A | 4A | 5A | 6A | 7A | 8A | 9A |
| Alkali- | (A11) | 100 | 100 | 100 | 100 | 100 | 100 | 100 | 100 | 100 |
| soluble | (A12) | | | | | | | | | |
| resin (A) | (A13) | | | | | | | | | |
| | (A14) | | | | | | | | | |
| Polymer- | (B11) | 7.5 | 7.5 | 7.5 | 7.5 | 7.5 | 7.5 | 7.5 | 7.5 | 7.5 |
| izable | | | | | | | | | | |
| compound | | | | | | | | | | |
| (B1) | | | | | | | | | | |
| Polymer- | (B21) | 42 | | 42 | 42 | 42 | 42 | 42 | 42 | 42 |
| izable | (B22) | | 27.5 | | | | | | | |
| compound | (B23) | | | | | | | | | |
| (B2) | | | | | | | | | | |
| Photo- | (C11) | 0.3 | 0.3 | 0.3 | 0.3 | 0.3 | 0.3 | 0.3 | 0.3 | |
| radical | (C12) | | | | | | | | | 0.3 |
| polymer- | (C21) | | | | | | | | | |
| ization | (C22) | 3 | 3 | 3 | 3 | 3 | 3 | 3 | 3 | 3 |
| initiator | (C23) | | | | | | | | | |
| (C) | | | | | | | | | | |
| Compound | (d11) | 0.05 | 0.05 | | | | | | | 0.05 |
| (D) | (d12) | | | 0.05 | | | | | | |
| | (d21) | | | | 0.05 | | | | | |
| | (d22) | | | | | 0.15 | | | | |
| | (d23) | | | | | | 0.15 | | | |
| | (d31) | | | | | | | 0.08 | | |
| | (d32) | | | | | | | | 0.08 | |
| Others (E) | (E1) | 0.1 | 0.1 | 0.1 | 0.1 | 0.1 | 0.1 | 0.1 | 0.1 | 0.1 |
| Solid content | | 66 | 63 | 66 | 66 | 66 | 66 | 66 | 66 | 66 |
| concentration | | | | | | | | | | |
| (mass %) | | | | | | | | | | |
| Degree of | | A | A | A | A | A | A | A | A | A |
| development | | | | | | | | | | |
| Pattern shape | | A | A | A | A | A | A | A | A | B |
| Whitening | | A | A | B | A | A | A | A | A | A |
| Resolution | | A | A | A | A | A | A | A | A | A |
| Components | | Example | Example | Example | Example | Example | Example | Example | Comparative | Comparative |
| (parts by mass) | | 10A | 11A | 12A | 13A | 14A | 15A | 16A | Example 1A | Example 2A |
| Alkali- | (A11) | 100 | 100 | 100 | 100 | | | | 100 | 100 |
| soluble | (A12) | | | | | 100 | | | | |
| resin (A) | (A13) | | | | | | 100 | | | |
| | (A14) | | | | | | | 100 | | |
| Polymer- | (B11) | 7.5 | 7.5 | 7.5 | 7.5 | 7.5 | 7.5 | 7.5 | 7.5 | 7.5 |
| izable | | | | | | | | | | |
| compound | | | | | | | | | | |
| (B1) | | | | | | | | | | |
| Polymer- | (B21) | 42 | 42 | 42 | 42 | 42 | 42 | 42 | 42 | 42 |
| izable | (B22) | | | | | | | | | |
| compound | (B23) | | | | | | | | | |
| (B2) | | | | | | | | | | |
| Photo- | (C11) | | | | 0.3 | 0.3 | 0.3 | 0.3 | 0.3 | |
| radical | (C12) | 0.3 | 0.3 | 0.3 | | | | | | 0.3 |
| polymeri- | (C21) | | | | | | | | | |
| zation | (C22) | 3 | 3 | 3 | | 3 | 3 | 3 | 3 | 3 |
| initiator | (C23) | | | | 3 | | | | | |
| (C) | | | | | | | | | | |
| Compound | (d11) | | | | 0.05 | 0.05 | 0.05 | 0.05 | | |
| (D) | (d12) | | | | | | | | | |
| | (d21) | | | | | | | | | |
| | (d22) | 0.15 | | | | | | | | |
| | (d23) | | | | | | | | | |
| | (d31) | | 0.08 | | | | | | | |
| | (d32) | | | 0.08 | | | | | | |
| Others (E) | (E1) | 0.1 | 0.1 | 0.1 | 0.1 | 0.1 | 0.1 | 0.1 | 0.1 | 0.1 |
| Solid content | | 66 | 66 | 66 | 66 | 66 | 66 | 66 | 66 | 66 |
| concentration | | | | | | | | | | |
| (mass %) | | | | | | | | | | |
| | | | | | | | | | Comparative | Comparative |
| Components | | Comparative | Comparative | Comparative | Comparative | Comparative | Comparative | Comparative | Example | Example |
| (parts by mass) | | Example 3A | Example 4A | Example 5A | Example 6A | Example 7A | Example 8A | Example 9A | 10A | 11A |
| Alkali- | (A11) | 100 | 100 | 100 | 100 | 100 | | | | |
| soluble | (A12) | | | | | | 100 | 100 | 100 | 100 |
| resin (A) | (A13) | | | | | | | | | |
| | (A14) | | | | | | | | | |
| Polymer- | (B11) | | | | | | 7.5 | 7.5 | | |
| izable | | | | | | | | | | |
| compound | | | | | | | | | | |
| (B1) | | | | | | | | | | |
| Polymer- | (B21) | 42 | 42 | 52 | 52 | 52 | 42 | 42 | 52 | 52 |
| izable | (B22) | 7.5 | | | | | | | | |
| compound | (B23) | | 7.5 | | | | | | | |
| (B2) | | | | | | | | | | |
| Photo- | (C11) | | | | | | 0.3 | | | |
| radical | (C12) | 0.3 | 0.3 | 0.3 | | | | 0.3 | | |
| polymeri- | (C21) | | | | 19 | 19 | | | 19 | 19 |
| zation | (C22) | 3 | 3 | 3 | 4 | 4 | 3 | 3 | 4 | 4 |
| initiator | (C23) | | | | | | | | | |
| (C) | | | | | | | | | | |
| Compound | (d11) | 0.05 | 0.05 | 0.05 | 0.05 | | | | 0.05 | |
| (D) | (d12) | | | | | | | | | |
| | (d21) | | | | | | | | | |
| | (d22) | | | | | | | | | |
| | (d23) | | | | | | | | | |
| | (d31) | | | | | | | | | |
| | (d32) | | | | | | | | | |
| Others (E) | (E1) | 0.1 | 0.1 | 0.1 | 0.1 | 0.1 | 0.1 | 0.1 | 0.1 | 0.1 |

| | | | | | | | | | |
|---|---|---|---|---|---|---|---|---|---|
| Solid content | 66 | 66 | 66 | 70 | 70 | 66 | 66 | 70 | 70 |
| concentration | | | | | | | | | |
| (mass%) | | | | | | | | | |

Details of each component shown in Table 1 are as follows.

### Alkali-Soluble Resin (A11)

An acrylic-based resin having the structural units marked with symbols a to e shown in Formula (A11) below (Mw: 12000, the content ratio of structural units a to e: a/b/c/d/e=10/15/25/20/30 (mass %))

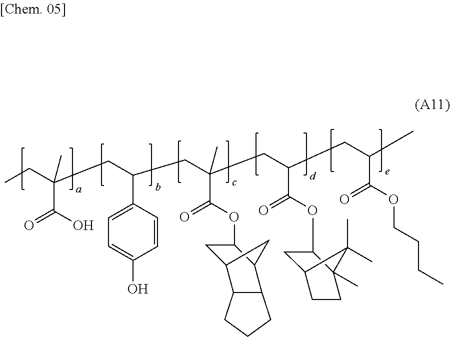

### Alkali-Soluble Resin (A12)

An acrylic-based resin having the structural units marked with symbols a to e shown in Formula (A12) below (Mw: 10000, the content ratio of structural units a to e: a/b/c/d/e=10/12/25/19/34 (mass %))

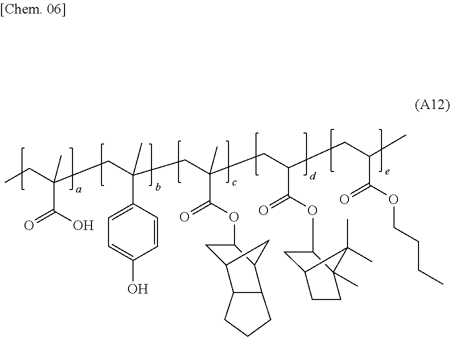

### Alkali-Soluble Resin (A13)

An acrylic-based resin having the structural units marked with symbols a to e shown in Formula (A13) below (Mw: 10000, the content ratio of structural units a to e: a/b/c/d/e=10/10/25/20/35 (mass %))

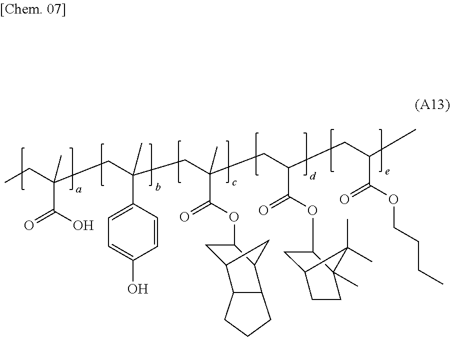

### Alkali-Soluble Resin (A14)

An acrylic-based resin having the structural units marked with symbols a to e shown in Formula (A14) below (Mw: 10000, the content ratio of structural units a to e: a/b/c/d/e=10/20/25/15/30 (mass %))

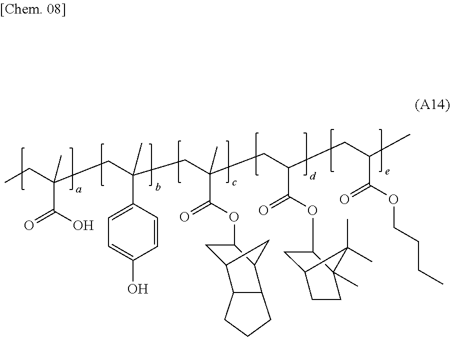

Polymerizable compound (B11): the compound represented by Formula (B11) below

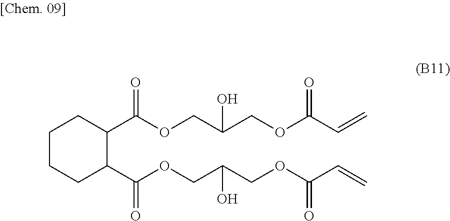 [SMILES: C=CC(=O)OCC(O)COC(=O)C1CCCCC1C(=O)OCC(O)COC(=O)C=C]

Polymerizable compound (B21): polyester acrylate (product name: “ARONIX M-8060”, manufactured by Toagosei Co., Ltd.)
Polymerizable compound (B22): product name: “A9300-1CL”, manufactured by Shin-Nakamura Chemical Co., Ltd.
Polymerizable compound (B23): product name: “Epoxy Ester 70PA”, manufactured by Kyoeisha Chemical Co., Ltd.
Photoradical polymerization initiator (C11): product name: “TR-PBG-3057”, manufactured by TRONLY
Photoradical polymerization initiator (C12): product name: “ADEKA ARKLS NCI-930”, manufactured by ADEKA Corporation
Photoradical polymerization initiator (C21): 2,2-dimethoxy-2-phenylacetophenone (product name: “Omnirad 651”, manufactured by IGM Resins B.V.)
Photoradical polymerization initiator (C22): 2,4,6-trimethylbenzoyl-diphenylphosphine oxide (product name: “Omnirad TPO H”, manufactured by IGM Resins B.V.)
Photoradical polymerization initiator (C23): bis(2,4,6-trimethylbenzoyl)-phenylphosphine oxide (product name: “Omnirad 819”, manufactured by IGM Resins B.V.)
Nitrogen-containing heterocyclic compound (d11): 1,2,3-benzotriazole
Nitrogen-containing heterocyclic compound (d12): benzimidazole
Thiol compound (d21): 2-mercaptobenzothiazole
Thiol compound (d22): product name: “C3TS-G”, manufactured by Shikoku Chemicals Corporation
Thiol compound (d23): pentaerythritol tetrakis(3-mercaptobutyrate) (product name: “Karenz MT PE1”, manufactured by Showa Denko K.K.)
Polymerization inhibitor (d31): the compound represented by Formula (d31) below

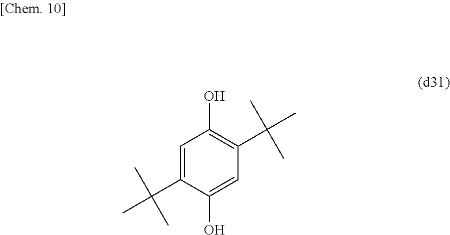 [SMILES: CC(C)(C)c1cc(O)c(C(C)(C)C)cc1O]

Polymerization inhibitor (d32): the compound represented by Formula (d32) below

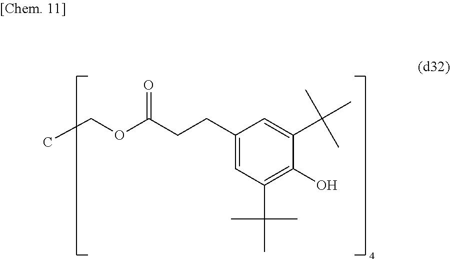

Other component (E1): product name: “FTERGENT FTX-218”, manufactured by NEOS Company Limited

### Manufacturing of Resist Pattern Film

### Example 1B

The photosensitive resin composition of Example 1A was applied using the spin coating method to a substrate in which a copper sputtered film was provided on a 12 inch silicon wafer, and heating at 120° C. or 130° C. on a hot plate was performed on a first layer for 300 seconds, a second layer for 600 seconds, and a third layer for 600 seconds; thus, resin coating films each having a film thickness of 350 μm were formed.

The above coating film was exposed to light via a patterned mask using a stepper (type: “FPA-5520iV”, manufactured by Canon Inc.), was immersed in a 2.38 mass % aqueous tetramethylammonium hydroxide solution for 720 seconds to be developed, and were then washed with pure water for 480 seconds; thereby, it was attempted to form a resist pattern film of 180 μm long×180 μm wide×340 μm deep and a resist pattern film of 200 μm long×200 μm wide×340 μm deep.

The “degree of development” of the photosensitive resin composition was evaluated according to the following criteria. The evaluation result is shown in Table 2.
A: The development speed of the film formed by heating at 130° C.×3 times was 50 μm/min or more.
B: The development speed of the film formed by heating at 130° C.×3 times was 40 μm/min or more and less than 50 μm/min.
C: The development speed of the film formed by heating at 130° C.×3 times was less than 40 μm/min.

The “pattern shape” of the resist pattern film was evaluated according to the following criteria. The evaluation result is shown in Table 2.
A: The pattern is rectangular, and there is observed no tension in an upper portion of the pattern or no cutting in a lower portion of the pattern.
B: The pattern is rectangular, but there is observed slight tension in an upper portion of the pattern and slight cutting in a lower portion of the pattern.
C: The rectangularity of the pattern is impaired, and there is observed significant tension in an upper portion of the pattern and significant cutting in a lower portion of the pattern.

The whitening of the unexposed portion was evaluated according to the following criteria. The evaluation result is shown in Table 2.
A: No whitening was observed even after heating of 130° C.×3 times.
B: No whitening was observed after heating of 120° C.×2 times+130° C.×1 time, but whitening was partially observed after heating of 130° C.×3 times.
C: Whitening was observed even after heating of 120° C.×2 times+130° C.×1 time.

Further, the smallest resist pattern film that was successfully formed among the resist pattern films attempted to form was obtained. The “resolution” of the photosensitive resin composition was evaluated according to the following criteria. The evaluation result is shown in Table 2.
A: The patterns up to the pattern of 180 μm long×180 μm wide×340 μm deep were successfully resolved.
B: Only the pattern of 200 μm long×200 μm wide×340 μm deep was successfully resolved.
C: The pattern of 200 μm long×200 μm wide×340 μm deep was impossible to resolve.

### Examples 2B to 16B and Comparative Examples 1B to 11B

Resist pattern films of Examples 2B to 16B and Comparative Examples 1B to 11B were formed by the same operation as in Example 1B except that the photosensitive resin compositions shown in Table 2 below were used instead of the photosensitive resin composition of Example 1A, and the degree of development, the pattern shape, the whitening of the unexposed portion, and resolution were evaluated. The evaluation result is shown in Table 2.

TABLE 2

| | Photosensitive resin | Degree of | Pattern | | |
|---|---|---|---|---|---|
| | composition | development | shape | Whitening | Resolution |
| Example 1B | Example 1A | A | A | A | A |
| Example 2B | Example 2A | A | A | A | A |
| Example 3B | Example 3A | A | A | B | A |
| Example 4B | Example 4A | A | A | A | A |
| Example 5B | Example 5A | A | A | A | A |
| Example 6B | Example 6A | A | A | A | A |
| Example 7B | Example 7A | A | A | A | A |
| Example 8B | Example 8A | A | A | A | A |
| Example 9B | Example 9A | A | B | A | A |
| Example 10B | Example 10A | A | B | A | A |
| Example 11B | Example 11A | A | B | A | A |
| Example 12B | Example 12A | A | B | A | A |
| Example 13B | Example 13A | A | B | A | A |
| Example 14B | Example 14A | A | B | A | B |
| Example 15B | Example 15A | A | B | A | B |
| Example 16B | Example 16A | B | B | A | B |
| Comparative Example 1B | Comparative Example 1A | A | A | C | B |
| Comparative Example 2B | Comparative Example 2A | A | B | C | B |
| Comparative Example 3B | Comparative Example 3A | A | C | A | C |
| Comparative Example 4B | Comparative Example 4A | A | C | A | C |
| Comparative Example 5B | Comparative Example 5A | B | B | A | C |
| Comparative Example 6B | Comparative Example 6A | B | C | A | C |
| Comparative Example 7B | Comparative Example 7A | B | C | C | C |
| Comparative Example 8B | Comparative Example 8A | A | B | C | C |
| Comparative Example 9B | Comparative Example 9A | B | B | C | C |
| Comparative Example 10B | Comparative Example 10A | B | C | A | C |
| Comparative Example 11B | Comparative Example 11A | B | C | C | C |

What is claimed is:

1. A photosensitive resin composition comprising:
(A) an alkali-soluble resin;
(B1) a polymerizable compound having at least two (meth)acryloyl groups and at least two hydroxy groups in one molecule and having a ring structure;
(C) a photoradical polymerization initiator;
(D) at least one compound selected from the group consisting of a nitrogen-containing heterocyclic compound (d1) containing two or more nitrogen atoms, a thiol compound (d2), and a polymerization inhibitor (d3); and
(F) a solvent.

2. The photosensitive resin composition according to claim 1, wherein the polymerizable compound (B1) has, in one molecule, at least two structures represented by Formula (1) below: 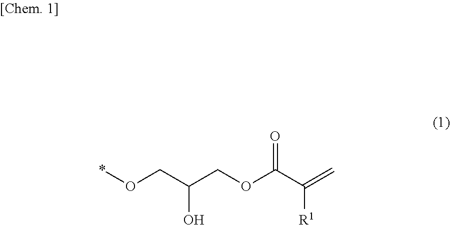
wherein R¹ represents a hydrogen atom or a methyl group, and * represents a bonding position.

3. The photosensitive resin composition according to claim 1, wherein the ring structure of the polymerizable compound (B1) is an alicyclic hydrocarbon structure.

4. The photosensitive resin composition according to claim 1, further comprising a polymerizable compound (B2) other than the polymerizable compound (B1).

5. The photosensitive resin composition according to claim 1, wherein the photoradical polymerization initiator (C) comprises an oxime-based photoradical polymerization initiator (C1).

6. The photosensitive resin composition according to claim 5, wherein the photoradical polymerization initiator (C) further comprises a non-oxime-based photoradical polymerization initiator (C2).

7. The photosensitive resin composition according to claim 1, wherein the compound (D) comprises the nitrogen-containing heterocyclic compound (d1).

8. The photosensitive resin composition according to claim 1, comprising the compound (D) in a range of 0.05 to 20 parts by mass with respect to 100 parts by mass of the polymerizable compound (B1).

9. The photosensitive resin composition according to claim 1, wherein the alkali-soluble resin (A) has a phenolic hydroxy group-containing structural unit represented by Formula (2) below: 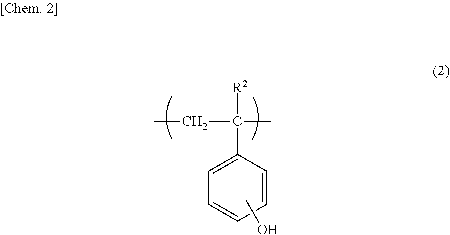
wherein R² represents a hydrogen atom or a methyl group.

10. The photosensitive resin composition according to claim 9, wherein a content of the phenolic hydroxy group-containing structural units in 100 mass % of the alkali-soluble resin (A) is in a range of 1 to 40 mass %.

11. A method for manufacturing a resist pattern film, comprising: a step (1) of applying the photosensitive resin composition according to claim 1 onto a substrate to form a resin coating film; a step (2) of exposing the resin coating film to light; and a step (3) of developing the resin coating film after exposure.

12. The method for manufacturing a resist pattern film according to claim 11, wherein a resist pattern film is formed on a copper film.

13. The method for manufacturing a resist pattern film according to claim 11, wherein a film thickness of the resin coating film formed by the step (1) is 250 μm or more.

14. A method for manufacturing a plated shaped article, comprising: a step of using, as a mask, a resist pattern film manufactured by the method according to claim 11 to perform plating treatment on the substrate.
